(19) United States
(12) Patent Application Publication
(10) Pub. No.: US 2010/0241271 A1
(43) Pub. Date: Sep. 23, 2010

(54) WAFER STORING CABINET AND STORAGE CONTROL METHOD THEREOF

(75) Inventors: Takao Shimizu, Hyogo (JP); Kunihisa Miyoshi, Ehime (JP); Toshitaka Oono, Tokyo (JP); Mareto Ishibashi, Tokyo (JP)

Correspondence Address: KRATZ, QUINTOS & HANSON, LLP, 1420 K Street, N.W., 4th Floor, WASHINGTON, DC, 20005, US

(73) Assignee: IHI CORPORATION, Tokyo (JP)

(21) Appl. No.: 12/294,499

(22) PCT Filed: Mar. 29, 2007
(86) PCT No.: PCT/JP2007/056956

§ 371 Date: Sep. 25, 2008

(30) Foreign Application Priority Data
Mar. 31, 2006 (JP) 2006-097034

(51) Int. Cl. B65G 1/00; H01L 21/677; H01L 21/673; B65G 49/07

(52) U.S. Cl. 700/218; 414/217.1

(57) ABSTRACT

The wafer storing cabinet has a storing cabinet main body 10 which is provided therein with storage cassettes 11, accommodation shelves 12A and 12B, and a wafer transfer section 20, and has an in/out storing cabinet 17, inert gas is supplied into the storing cabinet main body 10, in the wafer transfer section 20, wafers taken out from the transfer cassettes 15 and 16 which are transferred into the storing cabinet main body 10 are accommodated in the storage cassette 11, wafer taken out from the storage cassette 11 are accommodated in the transfer cassettes 15 and 16, the storage cassette 11 has a door which can secure a hermetic function, and the door is always closed except when a wafer is transferred into the storage cassette 11 and when a wafer is transferred out from the storage cassette 11.

### TECHNICAL FIELD

The present invention relates to a wafer storing cabinet and a storage control method thereof for temporarily storing a precision substrate such as a semiconductor wafer, a liquid crystal glass substrate and a magnetic disk especially at a producing stage.

### BACKGROUND TECHNIQUE

In a storage facility in a clean room, in order to prevent dust generated on a portion of a carry-in/out device which vertically moves a load-in/out mechanism from moving into an accommodation shelf, it is proposed to open a front surface of the accommodation shelf, to dispose a filter on the side of a rear surface and to supply clean air into defined accommodation spaces through the filter (patent document 1). There is also a wafer storing cabinet in which a wafer transfer section having a robot hand is provided in a wafer storing cabinet, and a wafer is held, in a non-contact manner, by blowing gas from the robot hand. When the system has the wafer transfer section of this kind, it is necessary to dispose an air tube for supplying blowing gas in the wafer storing cabinet (patent document 2).

[Patent Document 1] Japanese Patent Publication No. H1-41561

[Patent Document 2] Japanese Patent No. 2584144

### DISCLOSURE OF THE INVENTION

### Problem to be Solved by the Invention

Especially in the case of a semiconductor wafer, different gases are generated from the wafer itself depending upon producing stages and kinds of the wafer.

Such gas affects other wafers during storage.

There is a type of container in which a transfer cassette is accommodated as it is. In this case, to remove gas generated from a wafer, the transfer cassette itself has a purge function.

In the case of accommodation of this type, to accommodate the transfer cassette as it is, only one wafer is accommodated in one transfer cassette in some cases, and there is a problem that transfer efficiency and storing efficiency are poor.

Further, a wafer storing cabinet in which an air tube is disposed in a wafer storing cabinet has a problem that since the air tube can not be fixed, dust particles are generated, and the generated dust particles are rolled up by movement of the wafer transfer section and a wafer is contaminated.

Hence, it is an object of the present invention to provide a wafer storing cabinet and a storage control method thereof which have excellent transfer efficiency and accommodation efficiency, which prevent influence of dust, and which do not received influence of gas generated from a stored wafer.

It is another object of the invention to provide a wafer storing cabinet and a storage control method thereof which do not receive influence of dust particles generated by movement of a wafer transfer section.

### Means for Solving Problem

A first aspect of the present invention provides a wafer storing cabinet comprising a storing cabinet main body; the storing cabinet main body is provided therein with a plurality of storage cassettes in each of which a wafer is accommodated, an accommodation shelf in which the storage cassettes are disposed, and a wafer transfer section which is opposed to the accommodation shelf, the wafer storing cabinet further comprising an in/out storing cabinet which transfers a transfer cassette into and out from the storing cabinet main body, in which inert gas is supplied into the storing cabinet main body, in the wafer transfer section, the wafer taken out from the transfer cassette transferred into the storing cabinet main body is accommodated in the storage cassette, and the wafer taken out from the storage cassette is accommodated in the transfer cassette, wherein the storage cassette has a door to secure a hermetic function, and the door is always closed except when the wafer is transferred into the storage cassette and when the wafer is transferred out from the storage cassette.

According to a second aspect of the invention, in the wafer storing cabinet of the first aspect, it further comprises an input section for inputting wafer information stored in the transfer cassette which is transferred into the in/out storing cabinet, a wafer information memory section for storing the wafer information which is input by the input section, a storage cassette information memory section for storing at least an address and a vacant state concerning the storage cassette, a control section for determining the storage cassette which accommodates the wafer in the transfer cassette and for controlling the wafer transfer section, a control information memory section for storing operation instructing information in the wafer transfer section determined by the control section, and an output section for outputting, to the wafer transfer section, the operation instructing information which is read from the control information memory section, wherein the control section determines the storage cassette which stores the wafer in the transfer cassette from the wafer information which is input by the input section and from information stored in the storage cassette information memory section.

According to a third aspect of the invention, in the wafer storing cabinet of the first aspect, the wafer transfer section includes a door opening which opens and closes the door of the storage cassette, and a robot hand which moves the wafer.

According to a fourth aspect of the invention, in the wafer storing cabinet of the third aspect, the robot hand is provided at its upper surface with a plurality of gas blowing outlets, and the wafer transfer section is provided with a gas supply device which supplies gas to the gas blowing outlets.

According to a fifth aspect of the invention, in the wafer storing cabinet of the fourth aspect, a gas cylinder is used as the gas supply device, the wafer transfer section is provided with an air socket which supplies gas to the gas cylinder, and when the wafer transfer section is stopped, gas is supplied from the air socket.

According to a sixth of the invention, in the wafer storing cabinet of the fifth aspect, it further comprises a plurality of lines of accommodation shelves, and the accommodation shelves of the lines are respectively provided with a plurality of air plugs connected to the air socket.

A seventh aspect of the invention provides a storage control method of the wafer storing cabinet according to claim 2, the method comprises the steps of: transferring the transfer cassette to the storing cabinet main body; determining the storage cassette which stores the wafer by the control section from the wafer information accommodated in the transfer cassette which is transferred in; opening a door of the transfer cassette to take out the wafer in the transfer cassette by the wafer transfer section; closing the door of the transfer cassette, opening the door of the storage cassette, and accommodating the wafer in the storage cassette by the wafer transfer section; closing the door of the storage cassette; and transferring the transfer cassette out from the storing cabinet main body.

An eighth aspect of the invention provides a storage control method of the wafer storing cabinet according to claim 2, the method comprises the steps of: transferring the transfer cassette into the storing cabinet main body; determining, by the control section, the storage cassette which stores the wafer to be transferred out, from the wafer information to be accommodated in the transfer cassette which is transferred in; opening the door of the storage cassette to take out the wafer in the storage cassette by the wafer transfer section; closing the door of the storage cassette, opening a door of the transfer cassette and accommodating the wafer in the transfer cassette by the wafer transfer section; closing the door of the transfer cassette; and transferring the transfer cassette out from the storing cabinet main body.

### EFFECT OF THE INVENTION

According to the present invention, it is possible to isolate a wafer in each of storage cassettes, and to prevent a wafer from being affected by gas generated from another wafer.

### BRIEF DESCRIPTION OF THE DRAWINGS

FIG. 1 is a conceptual plan view of a wafer storing cabinet according to an embodiment of the present invention;

FIG. 2 is a conceptual perspective view of the wafer storing cabinet;

FIG. 3 is a partially cut-away plan view showing a robot hand of a wafer transfer section according to the embodiment of the invention;

FIG. 4 is a sectional side view showing the robot hand of the wafer transfer section;

FIG. 5 is a partial sectional side view showing a door opener of the wafer transfer section;

FIG. 6 is a sectional view of an essential portion showing a structure of the wafer transfer section on the side of a rail;

FIG. 7 is a perspective view of a storage cassette according to the embodiment;

FIG. 8 is a perspective view showing a state where a door of the storage cassette is opened;

FIG. 9 is a conceptual perspective view of a storage cassette according to another embodiment; and

FIG. 10 is a conceptual perspective view of a storage cassette according to another embodiment.

### EXPLANATION OF SYMBOLS

10 storing cabinet main body
11 storage cassette
12A accommodation shelf
12B accommodation shelf
15 transfer cassette
16 transfer cassette
20 wafer transfer section
21 robot hand
   21A hand portion
21H gas blowing outlet
21K gas supply device (gas cylinder)
23 air socket
31 input section
32 wafer information memory section
33 storage cassette information memory section
34 control section
35 control information memory section
36 output section

### BEST MODE FOR CARRYING OUT THE INVENTION

According to the wafer storing cabinet of the first aspect of the invention, the storage cassette has a door to secure a hermetic function, and the door is always closed except when the wafer is transferred into the storage cassette and when the wafer is transferred out from the storage cassette. With this aspect, since the storage cassette having the hermetic function is disposed in the storing cabinet main body to which inert gas is supplied, a wafer can be isolated in each of the storage cassette, and it is possible to prevent gas generated from a wafer from exerting an influencing upon other wafers.

According to the second aspect of the invention, in the wafer storing cabinet of the first aspect, the wafer storing cabinet further comprises an input section for inputting wafer information stored in the transfer cassette which is transferred into the in/out storing cabinet, a wafer information memory section for storing the wafer information which is input by the input section, a storage cassette information memory section for storing at least an address and a vacant state concerning the storage cassette, a control section for determining the storage cassette which accommodates the wafer in the transfer cassette and for controlling the wafer transfer section, a control information memory section for storing operation instructing information in the wafer transfer section determined by the control section, and an output section for outputting, to the wafer transfer section, the operation instructing information which is read from the control information memory section, wherein the control section determines the storage cassette which stores the wafer in the transfer cassette from the wafer information which is input by the input section and from information stored in the storage cassette information memory section. With this aspect, it is possible to select a storage cassette which accommodates a wafer, in accordance with a kind of wafers and stage of producing steps.

According to the third aspect of the invention, in the wafer storing cabinet of the first aspect, the wafer transfer section includes a door opening which opens and closes the door of the storage cassette, and a robot hand which moves the wafer. With this aspect, since the wafer transfer section is provided with the robot hand and the door opener, it is possible to shorten the opening time of the door of the storage cassette.

According to the fourth aspect of the invention, in the wafer storing cabinet of the third aspect, the robot hand is provided at its upper surface with a plurality of gas blowing outlets, and the wafer transfer section is provided with a gas supply device which supplies gas to the gas blowing outlets. With this aspect, a wafer can be transferred without coming into contact with the robot hand due to gas floating, and it is possible to prevent a wafer from being contaminated. Since gas is supplied to the gas blowing outlet from the gas supply device provided in the wafer transfer section, gas can be supplied to the wafer transfer section without drawing around an air hose which supplies gas. Therefore, when the wafer transfer section moves, it is possible to prevent the air hose from raising dust, and the wafer is not contaminated by the dust particles.

According to the fifth aspect of the invention, in the wafer storing cabinet of the fourth aspect, a gas cylinder is used as the gas supply device, the wafer transfer section is provided with an air socket which supplies gas to the gas cylinder, and when the wafer transfer section is stopped, gas is supplied from the air socket. With this aspect, it is possible to supply gas to the gas cylinder without exchanging the gas cylinder.

According to the sixth aspect of the invention, in the wafer storing cabinet of the fifth aspect, the wafer storing cabinet further including a plurality of lines of accommodation shelves, and the accommodation shelves of the lines are respectively provided with a plurality of air plugs connected to the air socket. With this aspect, when the operation of the accommodation shelf of the wafer transfer section in the line direction is stopped, i.e., when a wafer is stored in the accommodation shelf or a wafer is taken out from the accommodation shelf, gas can be supplied to the gas cylinder. Therefore, it is only necessary that the gas cylinder has necessary gas when the accommodation shelf of the wafer transfer section moves in the line direction and thus, the capacity of the gas cylinder can be reduced. Further, since gas can be supplied at a plurality of positions, there is no fear that gas supply is stopped during transportation, and the wafer storing cabinet can be operated reliably.

The seventh aspect of the invention provides a storage control method of the wafer storing cabinet of the second aspect, comprising the steps of: transferring the transfer cassette to the storing cabinet main body; determining the storage cassette which stores the wafer by the control section from the wafer information accommodated in the transfer cassette which is transferred in; opening a door of the transfer cassette to take out the wafer in the transfer cassette by the wafer transfer section; closing the door of the transfer cassette, opening the door of the storage cassette, and accommodating the wafer in the storage cassette by the wafer transfer section; closing the door of the storage cassette; and transferring the transfer cassette out from the storing cabinet main body. With this aspect, it is possible to reduce the influence of dust at the stage where a wafer is accommodated in the storage cassette and to recue the influence of gas generated from the wafer.

The eighth aspect of the invention provides a storage control method of the wafer storing cabinet of the second aspect, comprising the steps of: transferring the transfer cassette into the storing cabinet main body; determining, by the control section, the storage cassette which stores the wafer to be transferred out, from the wafer information to be accommodated in the transfer cassette which is transferred in; opening the door of the storage cassette to take out the wafer in the storage cassette by the wafer transfer section; closing the door of the storage cassette, opening a door of the transfer cassette and accommodating the wafer in the transfer cassette by the wafer transfer section; closing the door of the transfer cassette; and transferring the transfer cassette out from the storing cabinet main body. With this aspect, it is possible to reduce the influence of dust at the stage where a wafer is accommodated in the storage cassette and to recue the influence of gas generated from the wafer.

### Embodiment 1

Embodiments of the present invention will be explained in detail together with the Drawings.

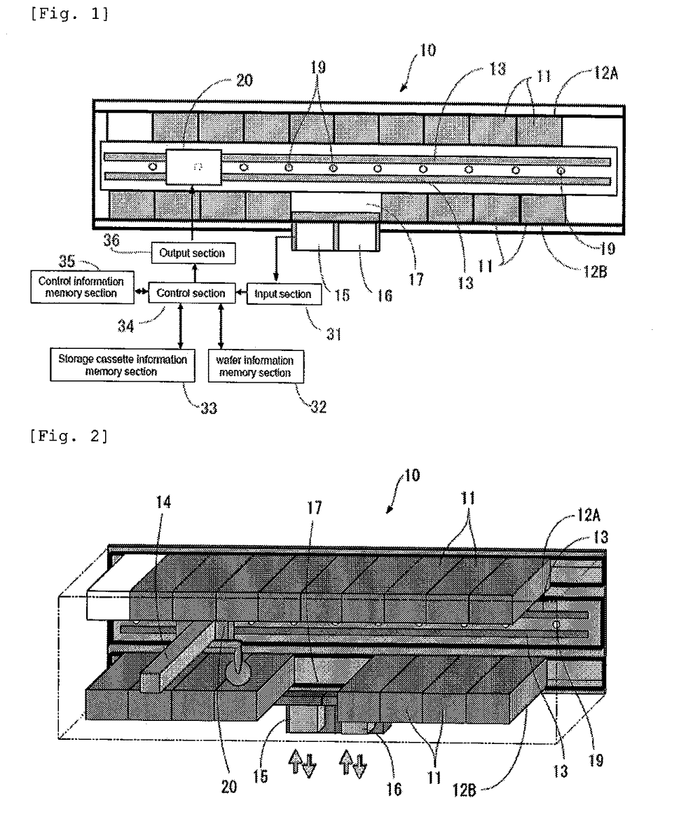

FIG. 1 is a conceptual plan view of a wafer storing cabinet according to an embodiment of the present invention. FIG. 2 is a conceptual perspective view of the wafer storing cabinet.

The wafer storing cabinet of the embodiment has a storing cabinet main body 10. The storing cabinet main body 10 is provided therein with a plurality of storage cassettes 11 each accommodates a wafer therein, accommodation shelves 12A and 12B in each of which the plurality of storage cassettes 11 are disposed, a moving member 14 disposed such as to be opposed to the accommodation shelves 12A and 12B, and a wafer transfer section 20 provided on the moving member 14. Rails 13 capable of moving the moving member 14 are disposed between the accommodation shelves 12A and 12B. The wafer transfer section 20 slides along a column provided on the moving member 14. Therefore, the wafer transfer section 20 can move along the rails 13 together with the moving member 14, the wafer transfer section 20 slides along the column of the moving member 14 and the wafer transfer section 20 can move two dimensionally.

Inert gas is supplied into the storing cabinet main body 10, and a hermetic state which is cut off from outside of the storing cabinet main body 10 is secured.

The storing cabinet main body 10 includes an in/out storing cabinet 17 which carries transfer cassettes 15 and 16 into and from the storing cabinet main body 10. For example, wafers to be stored are accommodated in the transfer cassette 15, and after the wafer is carried into the in/out storing cabinet 17, the wafer is taken out by the wafer transfer section 20, and the wafer is accommodated in the storage cassette 11. After all of the wafers to be moved to the storage cassette 11 are taken out, the transfer cassette 15 is carried out from the in/out storing cabinet 17. After a vacant transfer cassette 16 is carried into the in/out storing cabinet 17, a wafer taken out from the storage cassette 11 by the wafer transfer section 20 is accommodated. After all of wafers to be moved from the storage cassette 11 are accommodated, the transfer cassette 16 is carried out from the in/out storing cabinet 17.

The storage cassette 11 and the transfer cassettes 15 and 16 include doors (not shown) capable of securing hermetical functions. The storage cassette 11 and the transfer cassettes 15 and 16 are of single wafer type, and accommodate a plurality of wafers.

The wafer storing cabinet of the embodiment includes an input section 31 which inputs wafer information accommodated in the transfer cassette 15 to be carried into the in/out storing cabinet 17 or wafer information to be accommodated in the transfer cassette 16, a wafer information memory element 32 which stores the wafer information input by the input section 31, a storage cassette information memory section 33 which stores at least an address and a vacant state concerning the storage cassette 11, a control section 34 which determines the storage cassette 11 which stores a wafer in the transfer cassette 15, or determines the storage cassette 11 which stores a wafer accommodated in the transfer cassette 16, and controls the wafer transfer section 20, a control information memory section 35 which stores operation instructing information at the wafer transfer section 20 determined by the control section 34, and an output section 36 which outputs, to the wafer transfer section 20, operation instructing information which is read from the control information memory section 35. The control section 34 determines the storage cassette 11 which stores a wafer in the transfer cassette 15 from the wafer information which is input by the input section 31 and information stored in the storage cassette information memory section 33. The control section 34 determines the storage cassette 11 which as a wafer to be accommodated in the transfer cassette 16 from wafer information which is input by the input section 31 and information stored in the storage cassette information memory section 33.

A plurality of air plugs 19 are provided between the two rails 13. The air plug 19 is provided at every stop position of the moving member 14. That is, the plurality of air plugs 19 are provided in correspondence with the accommodation shelves 12 of the respective lines.

Next, a wafer transfer section suitable for the embodiment will be explained.

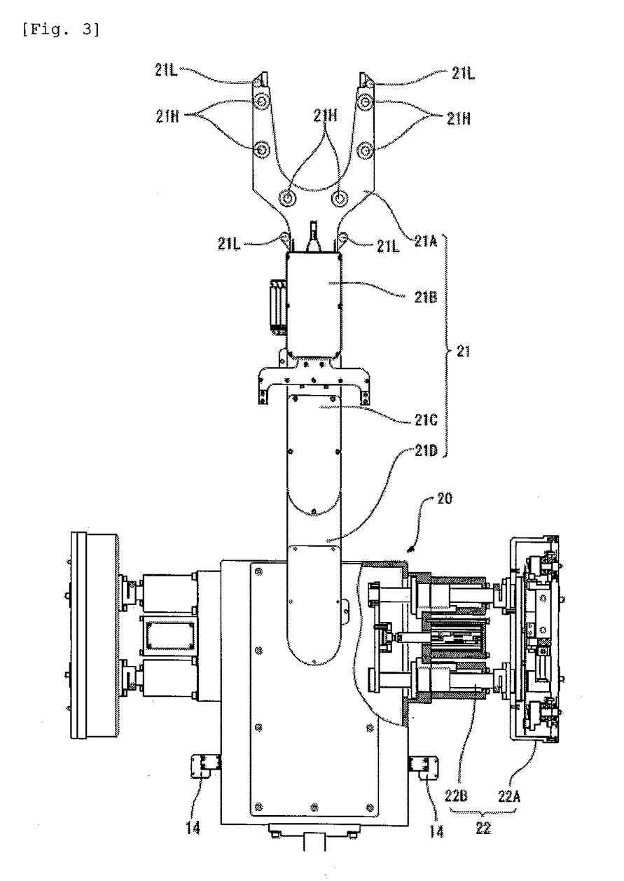

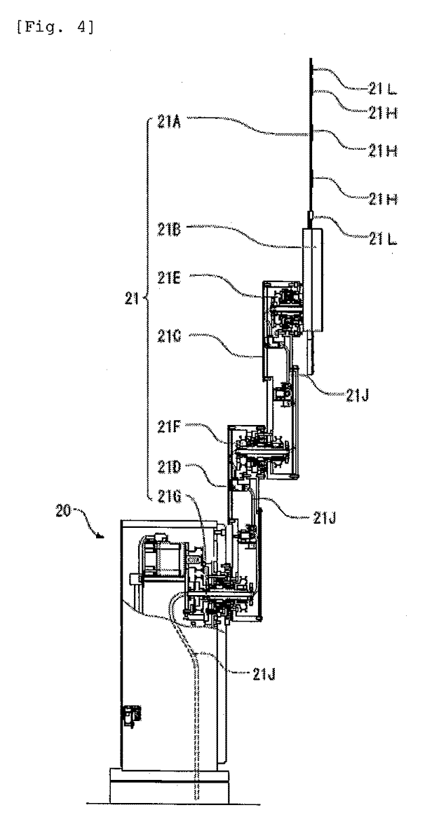

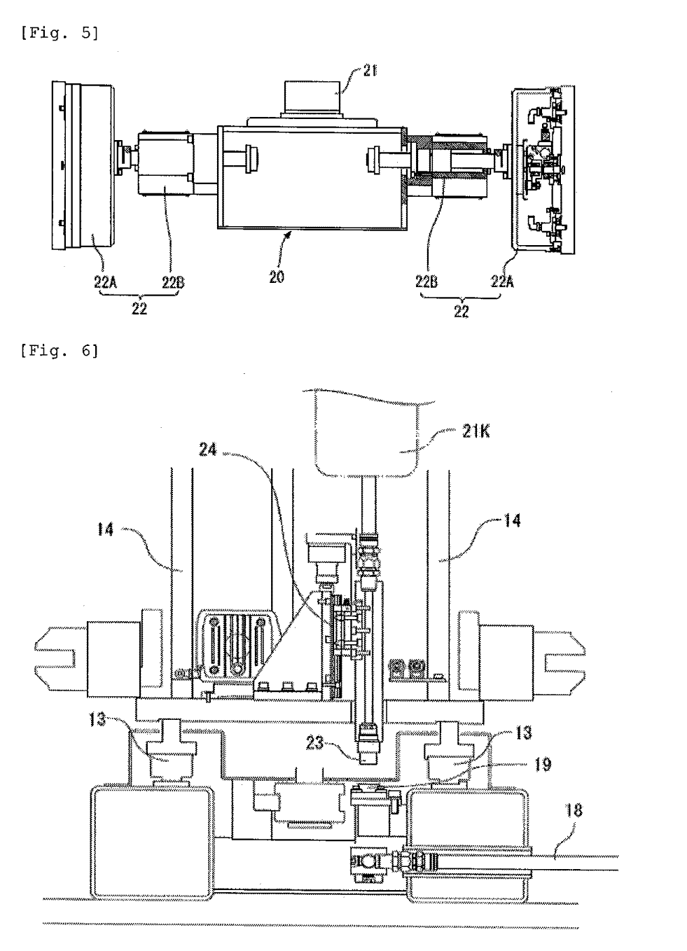

FIG. 3 is a partially cut-away plan view showing a robot hand of the wafer transfer section according to the embodiment of the invention. FIG. 4 is a sectional side view showing the robot hand of the wafer transfer section. FIG. 5 is a partial sectional side view showing a door opener of the wafer transfer section. FIG. 6 is a sectional view of an essential portion showing a structure of the wafer transfer section on the side of a rail.

As shown in the drawings, the wafer transfer section 20 of the embodiment includes a robot hand 21 which moves a wafer, and a door opener 22 which opens and closes the doors of the transfer cassettes 15 and 16.

The robot hand 21 includes a hand portion 21A on which a wafer is placed, and three arms 21B, 21C and 21D. The arm 21B has one end which holds the hand portion 21A, and the arm 21C and the turning shaft 21E are connected at the other end. The arm 21C is provided at its one end with a turning shaft 21E and at the other end with a turning shaft 21F. The arm 21D is connected to a main body of the wafer transfer section 20 through a turning shaft 21G. If the arms 21B, 21C and 21D are turned by the turning shafts 21E, 21F and 21G, a direction of the hand portion 21A, and a distance from the main body of the wafer transfer section 20 can freely be changed. As shown in FIG. 3, the hand portion 21A is provided at its upper surface (wafer placing surface) with a plurality of gas blowing outlets 21H and a plurality of rollers 21L. By blowing gas from the gas blowing outlets 21H, a wafer can be transferred without coming into contact with the upper surface of the hand portion 21A. A wafer is positioned by the rollers 21L. The gas blowing outlet 21H is connected to a tube 21J shown in FIG. 4, and the tube 21J is connected to a gas supply device (gas cylinder) 21K shown in FIG. 6. Gas injected from the gas blowing outlets 21H is supplied to the gas cylinder 21K. To supply gas to the gas blowing outlets 21H from the gas cylinder 21K provided in the moving member 14, it is unnecessary to connect a gas supply air hose to the wafer transfer section 20, and especially when the wafer transfer section 20 moves, it is possible to prevent dust from being generated by the air hose.

The door opener 22 includes a grasping portion 22A which sucks or grasps the door, and a movable portion 22B which changes a distance between the grasping portion 22A and the main body of the wafer transfer section 20.

The door openers 22 are provided on both sides to which the main body of the wafer transfer section 20 is opposed. One of the door openers 22 opens and closes the door of the storage cassette 11 disposed on the side of the accommodation shelf 12A shown in FIG. 2, and the other door opener 22 opens and closes the storage cassette 11 disposed on the side of the accommodation shelf 12B shown in FIG. 1 or FIG. 2. The other door opener 22 opens and closes the doors of the transfer cassettes 15 and 16.

The moving member 19 can move on the rails 13. As shown in FIG. 6, a gas supply pipe 18 is disposed below the rails 13, and the gas supply pipe 18 is provided with an air plug 19 whose upper portion is opened. The wafer transfer section 20 is provided with an air socket 23 which is connected to the gas cylinder 21K through a tube. A lower portion of the air socket 23 is opened, and the air socket 23 can vertically move by an elevating machine 24. The air socket 23 is lowered by the elevating machine 24 at the timing when the moving member 14 stops running, thereby connecting the air socket 23 and the air plug 19 with each other to supply compressed gas. If compressed gas is supplied by connecting the air socket 23 and the air plug 19 with each other as in this embodiment, it is possible to supply gas to the gas cylinder 21K without replacing the gas cylinder 21K.

As shown in FIGS. 1 and 2, the plurality of air plugs 19 are provided along the rails 13, and the air plugs 19 are provided in correspondence with the stop positions of the moving member 14. Therefore, the moving member 14 stops, and compressed gas can be supplied to the gas cylinder 21 during operation of the wafer transfer section 20.

In this embodiment, there is no air horse as described above, and it is possible to largely suppressing dust particles generated from the air hose caused when the moving member 14 runs.

The moving member 14 is stopped and compressed gas is supplied to the gas cylinder 21 during operation of the wafer transfer section 20. Therefore, the moving member 14 is not stopped only for supplying compressed gas, and wasteful waiting time is not generated.

Since the air plugs 19 are provided at all of the stop positions or necessary positions of the moving member 14, the air socket 23 and the air plug 19 are connected to each other without fail during the operation of the wafer transfer section 20. Therefore, the wafer transfer section 20 can be operated without concern for remaining amount of gas in the gas cylinder 21K. Since the air plugs 19 are provided at all of the stop positions of the moving member 14, the gas cylinder 21K can be omitted. In this case, to keep holding a wafer in the non-contact manner by the robot hand 21 during operation of the moving member 14, it is preferable that the gas cylinder 21K is provided. It is also effective that the air plug 19 is provided at a position where the moving member 14 always or frequently stops (e.g., at an opening of the in/out storing cabinet).

Next, a storage control method of the wafer storing cabinet according to the embodiment will be explained.

A wafer is stored in the wafer storing cabinet in accordance with the following steps.

First, the transfer cassette 15 is transferred into the wafer storing cabinet main body 10 from the in/out storing cabinet 17. The accommodated wafer information is displayed on a label or bar code of the transfer cassette 15, and the information is stored in an IC or a magnetic portion. Before and after the transfer cassette 15 is transferred into the storing cabinet main body 10, the wafer information displayed on or stored in the transfer cassette 15 is input from the input section 31. It is not always necessary to display or stored the wafer information on or in the transfer cassette 15, and the wafer information may be received from an information communication network by taking time association at which the transfer cassette 15 is transferred into the storing cabinet main body 10.

One of storage cassettes 11 which will store a wafer is determined by the control section 34 from the wafer information and information concerning the storage cassette 11 stored in the storage cassette information memory section 33. The information concerning the storage cassette 11 at least includes addresses for distinguishing positions of the storage cassettes 11, and data concerning the vacant state or the accommodation state. When a wafer is accommodated even partially, it is preferable that the wafer storing cabinet has information concerning this wafer. By grasping information concerning a wafer which is already accommodated, wafers of the same kind, or wafers which are processed at the same producing stage can be accommodated in the same storage cassette 11. A wafer at a stage where gas affecting others largely is generated can be accommodated in a storage cassette 11 adjacent to a specific location.

If the storage cassette 11 for storing a wafer is determined, operation instructing information is output from the output section 36 to the wafer transfer section 20, and the wafer transfer section 20 starts moving. If a wafer is to be stored, the wafer is taken out from the transfer cassette 15 and therefore, the operation is started before a storage cassette 11 which stores a wafer is determined and time required for storing a wafer can be shortened.

The wafer transfer section 20 opens the door of the transfer cassette 15 by the door opener 22, and a wafer in the transfer cassette 15 is taken out by the robot hand 21. After the wafer in the transfer cassette 15 is taken out by the robot hand 21, the door of the transfer cassette 15 is closed by the door opener 22. Thereafter, the wafer transfer section 20 moves toward the determined storage cassette 11.

If the wafer transfer section 20 reaches a position opposed to the determined storage cassette 11, the door of the storage cassette 11 is opened by the door opener 22, and the wafer held by the robot hand 21 is accommodated in the storage cassette 11. After the wafer is accommodated in the storage cassette 11 by the robot hand 21, the door of the storage cassette 11 is closed by the door opener 22.

If a plurality of wafers are to be stored from one transfer cassette 15 and if the wafers are moved by the robot hand 21 one by one as in this embodiment, the above operation is repeated by the necessary times.

If all of wafers to be moved are taken out and the door of the transfer cassette 15 is closed, the transfer cassette 15 is transferred out from the storing cabinet main body 10.

Wafers are transferred out from the wafer storing cabinet in accordance with the following steps.

First, the transfer cassette 16 is transferred into the storing cabinet main body 10 from the in/out storing cabinet 17. Wafer information concerning accommodation schedule is displayed on a label or bar code of the transfer cassette 16 to be transferred, or stored in an IC or a magnetic portion. Before and after the transfer cassette 16 is transferred into the storing cabinet main body 10, the wafer information displayed on or stored in the transfer cassette 16 is input from the input section 31. It is not always necessary to display or stored the wafer information on or in the transfer cassette 16, and the wafer information may be received from an information communication network by taking time association at which the transfer cassette 16 is transferred into the storing cabinet main body 10.

One of storage cassettes 11 to be transferred out is determined by the control section 34 from the wafer information and information concerning the storage cassette 11 stored in the storage cassette information memory section 33.

If a storage cassette 11 to be transferred out is determined, the operation instructing information is output from the output section 36 to the wafer transfer section 20, and the wafer transfer section 20 moves toward the determined storage cassette 11. If the wafer transfer section 20 reaches to a position opposed to the determined storage cassette 11, the door opener 22 opens the door of the storage cassette 11, and the robot hand 21 takes out a wafer in the storage cassette 11. After the wafer in the storage cassette 11 is taken out by the robot hand 21, the door opener 22 closes the door of the storage cassette 11. In this operation, compressed gas is not supplied to the gas cylinder 21K while the moving member 14 is moving, and gas is issued from the gas blowing outlet 21H by gas in the gas cylinder 21K. If the moving member 14 reaches a predetermined position, the air socket 23 and the air plug 19 are connected to each other during movement of the wafer transfer section 20, and the compressed gas is supplied. The connection between the air socket 23 and the air plug 19 is released at the timing when the operation of the wafer transfer section 20 is completed, and the moving member 14 moves toward the transfer cassette 16. When the moving member 14 moves, the wafer transfer section 20 is also moved along the column of the moving member 14 in necessary. If the wafer transfer section 20 reaches a position opposed to the transfer cassette 16, the door opener 22 opens the door of the transfer cassette 16, and a wafer held by the robot hand 21 is accommodated in the transfer cassette 16. After the wafer is accommodated in the transfer cassette 16 by the robot hand 21, the door opener 22 closes the door of the transfer cassette 16. In this case also, if the moving member 14 reaches a predetermined position, the air socket 23 and the air plug 19 are connected to each other during operation of the wafer transfer section 20, and compressed gas is supplied.

If a plurality of wafers are to be stored from one transfer cassette 16 and if the wafers are moved by the robot hand 21 one by one as in this embodiment, the above operation is repeated by the necessary times.

If all of wafers to be moved are accommodated and the door of the transfer cassette 16 is closed, the transfer cassette 16 is transferred out from the storing cabinet main body 10.

According to the embodiment, as described above, when a wafer is stored in the storage cassette 11 and when a wafer is transferred out from the storage cassette 11, the door is opened or closed whenever the wafer is accommodated and taken out, and influence of gas generated from dust or wafer can be reduced.

Next, the storage cassette suitable for the wafer storing cabinet of the present invention will be explained.

As the storage cassette 11 of the embodiment, the same structure as that of the transfer cassette 15, 16 can be used.

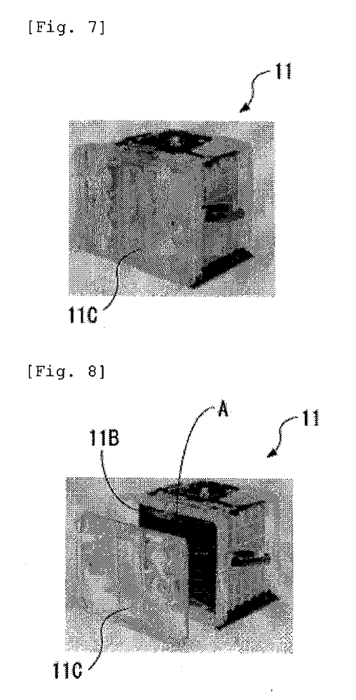

FIG. 7 is a perspective view of a storage cassette according to the embodiment. FIG. 8 is a perspective view showing a state where a door of the storage cassette is opened.

The storage cassette 11 of the embodiment includes a bottomed side plate 11A covering an outer periphery, projections 11B provided at predetermined intervals from one another on opposed surfaces of the side plate 11A, and a door 11C for covering a front surface. Wafers A are accommodated on the projections 11B.

As shown in FIG. 7, the storage cassette 11 of the embodiment is in a hermetical state when the door 11C closes the front surface.

If the transfer cassette (FOUP) is used as the storage cassette 11 as in this embodiment, the transfer cassette can be detached from the accommodation shelf and cleaned as needed.

### Embodiment 2

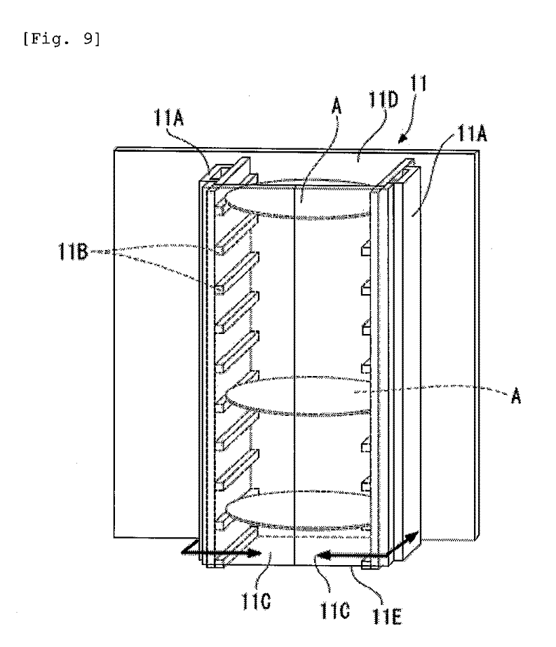

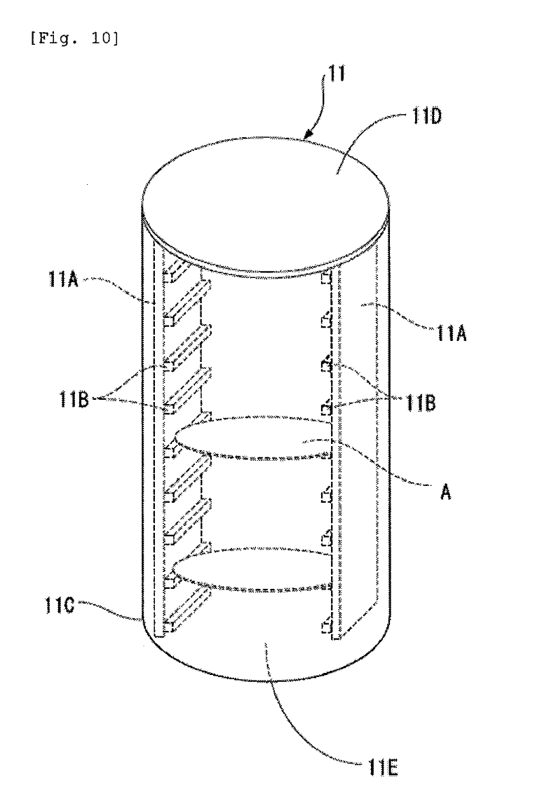

FIG. 9 is a conceptual perspective view of a storage cassette according to another embodiment.

In the embodiment shown in FIG. 9, a storage cassette 11 includes a pair of side plates 11A, projections 11B provided at predetermined intervals from one another on opposed surfaces of the side plates 11A, and doors 11C covering a front surface. Wafers A are accommodated on the projections 11B as illustrated.

The doors 11C of the embodiment open the front surface when the doors 11C are disposed in parallel to the side plates 11A, and if the doors 11C are pulled out toward the front surface from the state where the doors 11C are in parallel to the side plates 11A and then the angles thereof are changed by 90°, the doors 11C cover the front surface. The storage cassette 11 also includes a top plate 11D and a bottom plate 11E, and in a state where the doors 11C cover the front surface, the storage cassette 11 is brought into the hermetic state.

### Embodiment 3

FIG. 10 is a conceptual perspective view of a storage cassette according to another embodiment.

In the embodiment shown in FIG. 10, the storage cassette 11 includes a pair of side plates 11A, projections 11B provided at predetermined intervals from one another on opposed surfaces of the side plates 11A, and a door 11C using a portion of a cylindrical body as an opening. Wafers A are accommodated on the projections 11B as illustrated.

According to the door 11C of the embodiment, the front surface is opened and closed by rotating one of double cylindrical bodies. The storage cassette 11 includes a top plate 11D and a bottom plate 11E. In a state where the front surface is covered with the door 11C, the storage cassette 11 is in the hermetic state.

The opening and closing operations shown in FIGS. 9 and 10 are carried out by the door opener 22 provided on the wafer transfer section 20, but the wafer transfer section 20 may not be provided with the door opener 22, and the door may be opened and closed on the side of the storage cassette 11.

Since this embodiment does not have the air hose, it is possible to largely suppress dust particles generated from the air hose caused when the moving member 14 runs.

Although one rail 13 is disposed in the wafer storing cabinet in this embodiment, a plurality of rails 13 may be provided, and a moving member 14 having the wafer transfer section 20 may be provided with respect to each rail 13. Further, one rail 13 may be provided with a plurality of moving members 14. One moving member 14 may be provided with one wafer transfer section 20, or each moving member 14 may be provided with a plurality of wafer transfer sections 20. One wafer transfer section 20 may be provided with a plurality of robot hands 21.

Although the gas supply pipe 18 is disposed below the rail 13 and on the side of the floor in this embodiment, the gas supply pipe 18 may be disposed on the side of a ceiling surface of the wafer storing cabinet. When the gas supply pipe 18 is disposed on the side of the ceiling surface of the wafer storing cabinet, the air plug 19 is provide from the ceiling surface downward, and the moving member 19 is provided at its upper portion with the air socket 23. The gas supply pipes 18 may be provided on a surface of the wafer storing cabinet where the accommodation shelves 12A and 12B are installed.

Although the air socket 23 is vertically moved by the elevating machine 24 in this embodiment, the elevating machine 24 may be provided on the side of the air plug 19, the elevating machine 24 may be provided on each of the air plug 19, and both the air socket 23 and the air plug 19 may be operated.

Although the gas cylinder is used as the gas supply device 21K in this embodiment, a compressor may be used as the device. If the compressor is used as the device, gas in the wafer storing cabinet is sucked, and the sucked gas is purified through a filter and then compressed and supplied to the robot hand.

Examples of gas used for the gas supply device 21K are air, nitrogen and inert gas such as argon.

### INDUSTRIAL APPLICABILITY

The present invention is suitable for the wafer storing cabinet and the storage control method thereof. The invention is also suitable for a storing cabinet for a liquid crystal glass substrate, a magnetic disk or other articles which need to be stored in a clean room, and the invention is also suitable for a storage control method thereof.

1. A wafer storing cabinet comprising a storing cabinet main body; the storing cabinet main body is provided therein with a plurality of storage cassettes in each of which a wafer is accommodated, an accommodation shelf in which the storage cassettes are disposed, and a wafer transfer section which is opposed to the accommodation shelf, the wafer storing cabinet further comprising an in/out storing cabinet which transfers a transfer cassette into and out from the storing cabinet main body, in which
inert gas is supplied into the storing cabinet main body,
in the wafer transfer section, the wafer taken out from the transfer cassette transferred into the storing cabinet main body is accommodated in the storage cassette, and the wafer taken out from the storage cassette is accommodated in the transfer cassette, wherein
the storage cassette has a door to secure a hermetic function, and
the door is always closed except when the wafer is transferred into the storage cassette and when the wafer is transferred out from the storage cassette.

2. The wafer storing cabinet according to claim 1, further comprising an input section for inputting wafer information stored in the transfer cassette which is transferred into the in/out storing cabinet, a wafer information memory section for storing the wafer information which is input by the input section, a storage cassette information memory section for storing at least an address and a vacant state concerning the storage cassette, a control section for determining the storage cassette which accommodates the wafer in the transfer cassette and for controlling the wafer transfer section, a control information memory section for storing operation instructing information in the wafer transfer section determined by the control section, and an output section for outputting, to the wafer transfer section, the operation instructing information which is read from the control information memory section, wherein the control section determines the storage cassette which stores the wafer in the transfer cassette from the wafer information which is input by the input section and from information stored in the storage cassette information memory section.

3. The wafer storing cabinet according to claim 1, wherein the wafer transfer section includes a door opening which opens and closes the door of the storage cassette, and a robot hand which moves the wafer.

4. The wafer storing cabinet according to claim 3, wherein the robot hand is provided at its upper surface with a plurality of gas blowing outlets, and the wafer transfer section is provided with a gas supply device which supplies gas to the gas blowing outlets.

5. The wafer storing cabinet according to claim 4, wherein a gas cylinder is used as the gas supply device, the wafer transfer section is provided with an air socket which supplies gas to the gas cylinder, and when the wafer transfer section is stopped, gas is supplied from the air socket.

6. The wafer storing cabinet according to claim 5, further comprising a plurality of lines of accommodation shelves, and the accommodation shelves of the lines are respectively provided with a plurality of air plugs connected to the air socket.

7. A storage control method of the wafer storing cabinet according to claim 2, comprising the steps of: transferring the transfer cassette into the storing cabinet main body; determining the storage cassette which stores the wafer by the control section from the wafer information accommodated in the transfer cassette which is transferred in; opening a door of the transfer cassette to take out the wafer in the transfer cassette by the wafer transfer section; closing the door of the transfer cassette, opening the door of the storage cassette, and accommodating the wafer in the storage cassette by the wafer transfer section; closing the door of the storage cassette; and transferring the transfer cassette out from the storing cabinet main body.

8. A storage control method of the wafer storing cabinet according to claim 2, comprising the steps of: transferring the transfer cassette into the storing cabinet main body; determining, by the control section, the storage cassette which stores the wafer to be transferred out, from the wafer information to be accommodated in the transfer cassette which is transferred in; opening the door of the storage cassette to take out the wafer in the storage cassette by the wafer transfer section; closing the door of the storage cassette, opening a door of the transfer cassette and accommodating the wafer in the transfer cassette by the wafer transfer section; closing the door of the transfer cassette; and transferring the transfer cassette out from the storing cabinet main body.
